(19) United States
(12) Patent Application Publication
(10) Pub. No.: US 2025/0029651 A1
(43) Pub. Date: Jan. 23, 2025

(54) PERFORMING LOGICAL OPERATIONS IN MEMORY

(71) Applicant: Micron Technology, Inc., Boise, ID (US)

(72) Inventors: Glen E. Hush, Boise, ID (US); Troy A. Manning, Meridian, ID (US); Timothy P. Finkbeiner, Boise, ID (US); Troy D. Larsen, Meridian, ID (US); Peter L. Brown, Eagle, ID (US)

(21) Appl. No.: 18/763,330

(22) Filed: Jul. 3, 2024

Related U.S. Application Data
(60) Provisional application No. 63/527,457, filed on Jul. 18, 2023.

(51) Int. Cl. G11C 11/4091; G11C 11/408; H03K 19/20

(52) U.S. Cl. CPC G11C 11/4091; G11C 11/4085; H03K 19/20

(57) ABSTRACT

Methods, systems, and devices related to performing logical operations using multiple digit lines. At least two digit lines coupled to the same sense amplifier can be used for the logical operations. For example, two word lines on one digit line and one word line on another digit line can be substantially concurrently activated to perform a particular logical operation. These three word lines are respectively coupled to memory cells configured to store either operands of operation or a reference data value for the particular logical.

### CROSS-REFERENCE TO RELATED APPLICATION

This application claims the benefit of U.S. Provisional Application No. 63/527,457, filed on Jul. 18, 2023, the contents of which are incorporated herein by reference.

### TECHNICAL FIELD

The present disclosure relates generally to semiconductor memory and methods, and more particularly, to apparatuses, systems, and methods of performing logical operations in memory.

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes Random Access Memory (RAM), Dynamic Random Access Memory (DRAM), Static Random Access Memory (SRAM), Synchronous Dynamic Random Access Memory (SDRAM), and Thyristor Random Access Memory (TRAM), among others. Non-volatile memory can provide persistent data by retaining stored data when not powered and can include NAND flash memory, NOR flash memory, Ferroelectric Random Access Memory (FeRAM), and resistance variable memory such as Phase Change Random Access Memory (PCRAM), Resistive Random Access Memory (RRAM), and Magnetoresistive Random Access Memory (MRAM), such as Spin Torque Transfer Random Access Memory (STTRAM), among others.

Electronic systems may include processing resources (e.g., one or more processors), which may retrieve and execute instructions and store the results of the executed instructions to a suitable location. A processor may include functional units such as arithmetic logic unit (ALU) circuitry, floating point unit (FPU) circuitry, and/or a combinatorial logic block, for example, which may be used to execute instructions by performing logical operations such as AND, OR, NOT, NAND, NOR, and XOR, and invert (e.g., inversion) logical operations on data (e.g., one or more operands).

### BRIEF DESCRIPTION OF THE DRAWINGS

FIG. 1 illustrates a functional block diagram in the form of a memory system including a memory device in which logical operations are performed using multiple digit lines in accordance with a number of embodiments of the present disclosure.

FIG. 2 is a schematic diagram illustrating rows of memory cells of a memory array and sense amplifiers that can perform logical operations using multiple digits lines in accordance with a number of embodiments of the present disclosure.

FIG. 3 is a schematic diagram illustrating rows of memory cells of a memory array and sense amplifiers that can perform logical operations using multiple digits lines in accordance with a number of embodiments of the present disclosure.

FIG. 4 illustrates various voltage levels of voltages at which digit lines are biased while a logical operation is being performed in accordance with a number of embodiments of the present disclosure.

FIG. 5 illustrates various voltage levels of voltages at which digit lines are biased while another logical operation is being performed in accordance with a number of embodiments of the present disclosure.

### DETAILED DESCRIPTION

Systems, apparatuses, and methods related to performing logical operations in memory are described. Embodiments of the present disclosure can include performing logical operations by activating (e.g., opening) at least three word lines, at least one of which being a reference word line (e.g., a word line coupled to a memory cell that is coupled to a reference digit line). In various embodiments, two of the three word lines (e.g., non-reference word lines) are respectively coupled to memory cells storing operands for the logical operations, with the two memory cells being coupled to a same digit line (e.g., a non-reference digit line). In this example, the third word line (e.g., a reference word line) is coupled to a third memory cell to which a reference digit line is coupled, with the reference digit line being complementary to the non-reference digit line. That is, the reference digit line and the non-reference digit line are commonly coupled to a same sense amplifier. The memory cell coupled to the reference word line and to the reference digit line can be referred to as a reference memory cell and be configured to store a “reference” data value (alternatively referred to as “reference value”) for the logical operations. As used herein, the term “reference data value” refers to a data value (e.g., “0” or “1”) that does not correspond to operands of a logical operation. Rather, the reference data value is used to obtain a desired output of a corresponding/particular logical operation. In some embodiments, reference data values for different logical operations may also be different.

Some prior approaches to performing logical operations in memory can include activating word lines located solely on a “non-reference side” of a sense amplifier without activating a word line on the “reference side” of the sense amplifier. As used herein, the terms “reference side” and “non-reference side” are used herein to refer to denote complementary sides of a sense amplifier coupled to complementary digit lines (e.g., D and D*). It will be appreciated that in a folded digit line scheme, both of the complementary digit lines are located on a same physical side of the array (e.g., with the reference and non-reference word lines being in the same sub-array). These prior approaches can have drawbacks as the more word lines activated on the same side, the higher chance of noise and interference among the word lines, which potentially leads to errors in sensing data values and/or voltages on those memory cells with which the logical operations are performed.

Various embodiments of the present disclosure address the above and other deficiencies by providing apparatuses and methods that perform logical operations by activating (e.g., three) word lines on different sides (non-reference and reference sides) so as to reduce a quantity of word lines activated on each side of the memory array. For example, logical operations can be performed on memory cells (e.g., coupled to the two word lines located) on the non-reference side along with the reference memory cell on the reference side. This reduces the risk of noise and interference that may occur from activating more/multiple word lines on the same side and further provides a better precise voltage tuning capability of (e.g., the reference voltage corresponding to) the reference data value stored on the reference memory cell. This capability further enhances the ability to perform what was desired to be performed, instead of a different logical operation being undesirably performed due to the poor voltage tuning capability of the reference data value; thereby, allowing performance of logical operations according to embodiments of the present disclosure implementable in complex schemes, such as neural network schemes.

As used herein, the singular forms “a,” “an,” and “the” include singular and plural referents unless the content clearly dictates otherwise. Furthermore, the word “may” is used throughout this application in a permissive sense (e.g., having the potential to, being able to), not in a mandatory sense (e.g., must). The term “include,” and derivations thereof, mean “including, but not limited to.” As used herein, “coupled to” or “coupled with” generally refers to a connection between components, which can be an indirect communicative connection or direct communicative connection (e.g., without intervening components), whether wired or wireless, including connections such as electrical, optical, magnetic, and the like. The terms “data” and “data values” are used interchangeably herein and can have the same meaning, as appropriate to the context.

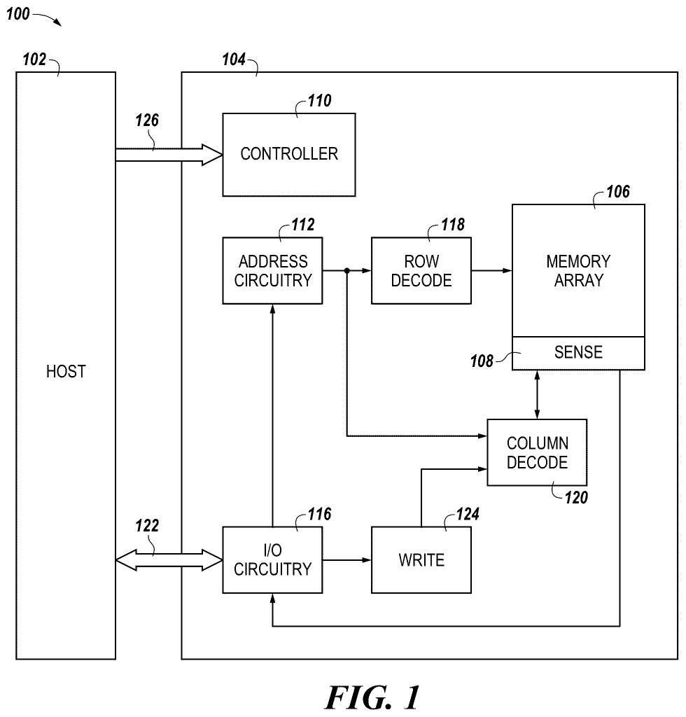

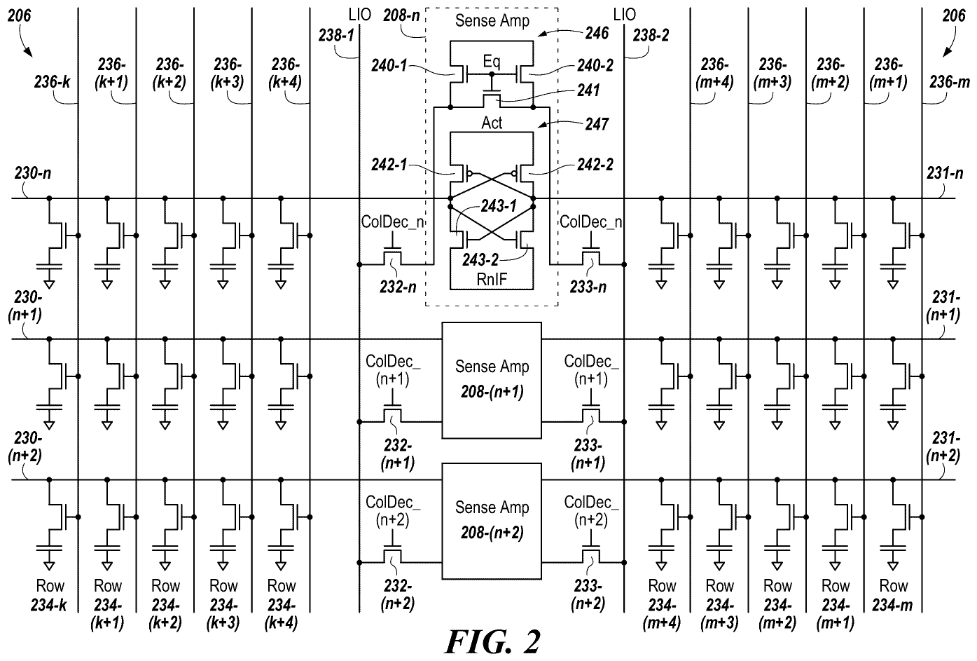

The figures herein follow a numbering convention in which the first digit or digits correspond to the drawing figure number and the remaining digits identify an element or component in the drawing. Similar elements or components between different figures may be identified by the use of similar digits. For example, element “108” can represent element “8” in FIG. 1, and a similar element can be labeled “208” in FIG. 2. Analogous elements within a figure may be referenced with a hyphen and extra numeral or letter. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 is a block diagram of an apparatus in the form of a computing system 100 including a memory device 104 in which logical operations are performed using multiple digit lines in accordance with a number of embodiments of the present disclosure. As used herein, a memory device 104, a memory array 106, and/or sense amplifiers 108 (“sense” in FIG. 1) might also be separately considered an “apparatus.” For clarity, the computing system 100 has been simplified to focus on features with particular relevance to the present disclosure (providing the host 102 with capabilities associated with an SRAM resource via the sense amplifiers 108, for instance). Although the example shown in FIG. 1 illustrates a system having a Von Neumann architecture, embodiments of the present disclosure can be implemented in non-Von Neumann architectures (e.g., a Turing machine), which may not include one or more components (e.g., CPU, ALU, etc.) often associated with a Von Neumann architecture.

The computing system 100 includes a host 102 coupled (e.g., connected) to the memory device 104, which includes the memory array 106. The computing system 100 can be a component or a resource of a personal laptop computer, a desktop computer, a digital camera, a smart phone, or a memory card reader, for example, among various other types of electronic devices. The host 102 can be or include a processing device, such as an CPU. The host 102 can include a system motherboard and/or backplane and can include one or more processing devices (e.g., one or more processors such as an CPU, microprocessors, controlling circuitry). The computing system 100 can include the host 102 and the memory device 104 as separate and distinct integrated circuits or the host 102 and the memory device 104 as components on the same (a single) integrated circuit (e.g., the host 102 on-chip with the memory device 104). In some embodiments, the memory device 104 can include components coupled to respective substrates and those substrates can be coupled to another substrate, such as a printed circuit board (PCB). The computing system 100 can be, for instance, a component or a resource of a server system and/or a high performance computing (HPC) system and/or a portion thereof.

The memory array 106 can be a DRAM array, SRAM array, STT RAM array, PCRAM array, TRAM array, RRAM array, FeRAM array, NAND flash array, and/or NOR flash array, for instance. A FeRAM array can include ferroelectric capacitors and can perform bit storage based on an amount of voltage or charge applied thereto. The memory array 106 can comprise memory cells arranged in rows coupled by access lines (which may be referred to herein as word lines or select lines) and columns coupled by sense lines. Although a single memory array 106 is shown in FIG. 1, embodiments are not so limited. For instance, the memory device 104 can include one or more memory arrays 106 (e.g., a number of banks of DRAM cells).

The memory device 104 can include address circuitry 112 to latch address signals provided over an I/O bus 122 (e.g., a data bus) through I/O circuitry 116. Address signals can be received and decoded by a row decoder 118 and a column decoder 120 to access the memory array 106. Data can be read from the memory array 106 by sensing voltage and/or current changes on the digit lines using the sense amplifiers 108. As described herein, the sense amplifiers 108 can be one or more sense amplifier stripes. The sense amplifiers 108 can be used to read and latch a page (e.g., row) of data from the memory array 106. The I/O circuitry 116 can be used for bi-directional data communication with the host 102 over the I/O bus 122. The write circuitry 124 can be used to write data to the memory array 106.

A controller 110 can decode signals provided by a control bus 126 from the host 102. These signals can include chip enable signals, write enable signals, and address latch signals that are used to control operations performed on the memory array 106, including data read, data write, and data erase operations. In various embodiments, the controller 110 can be responsible for executing instructions from the host 102. The controller 110 can be a state machine, a sequencer, or some other type of controller.

In some embodiments, the sense amplifiers 108 can be used to perform logical operations using data stored in the memory array 106 and/or data stored in the sense amplifiers 108 as inputs and store the results of the logical operations the memory array 106 and/or data stored in the sense amplifiers 108 without transferring data via a sense line address access (e.g., without firing a column decode signal). As such, various compute functions can be performed using, and within, the sense amplifiers 108 rather than (or in association with) being performed by processing resources external to the sense amplifiers 108 (e.g., by a processor associated with the host 102 and/or other processing circuitry, such as ALU circuitry, of the memory device 104 (e.g., of the controller 110 or elsewhere)).

FIG. 2 is a schematic diagram illustrating rows 234 of memory cells of a memory array 206 and sense amplifiers 208 that can perform logical operations using multiple digits lines 230, 231 in accordance with a number of embodiments of the present disclosure. The memory array 206 includes a first subset including rows of memory cells 234-m, 234-(m+1), 234-(m+2), 234-(m+3), and 234-(m+4) coupled to respective word lines (e.g., 236-m, 236-(m+1), 236-(m+2), 236-(m+3), and 236-(m+4), respectively). The memory array 206 includes a second subset portion including rows of memory cells 234-k, 234-(k+1), 234-(k+2), 234-(k+3), and 234-(k+4) coupled to respective word lines (e.g., 236-k, 236-(k+1), 236-(k+2), 236-(k+3), and 236-(k+4), respectively). As used herein, “subset” is used for identification purposes and does not necessarily imply physical or logical characteristics (e.g., boundaries) of the memory array 206. The rows of the subarrays are referred to collectively as the rows 234 and the word lines of the subarrays are referred to collectively as the word lines 236.

The memory array 206 includes columns of memory cells corresponding respective complementary digit line pairs 230-n/231-n, 230-(n+1)/231-(n+1), and 230-(n+2)/231-(n+2). The columns of memory cells include respective sense amplifiers 208-n, 208-(n+1), and 208-(n+2) (referred to collectively as the sense amplifiers 208) that can be operated in multiple modes in accordance with embodiments described herein. The memory array 206 and the sense amplifiers 208 can be analogous to the memory array 106 and the sense amplifiers 108 described in association with FIG. 1. Although FIG. 2 illustrates five word lines 236 (e.g., five rows 234) coupled to a local I/O line (e.g., LIO 238-1 and LIOF 238-2) via three digit lines 230 and three sense amplifiers 208 (e.g., three columns), embodiments can include greater or fewer than five word lines and greater or fewer than three digit lines coupled to a local I/O line. Also, FIG. 2 illustrates the complementary digit line pairs 230-n/231-n, 230-(n+1)/231-(n+1), and 230-(n+2)/231-(n+2) in an open digit line architecture; however, embodiments can include a folded digit line architecture, for example.

In this example, the memory array 206 includes 1T1C (one transistor one capacitor) DRAM memory cells with each memory cell including an access device (e.g., a transistor) and a storage element (e.g., a capacitor). In some embodiments, the memory cells can be destructive read memory cells (e.g., reading data stored in a memory cell destroys the data such that the data originally stored in the memory cell is refreshed after being read).

FIG. 2 illustrates an example configuration for the sense amplifiers 208 described herein (illustrated schematically by the sense amplifier 208-n). Embodiments of the present disclosure are not limited to the example sense amplifier configuration illustrated by FIG. 2, and can be, for example, a current-mode sense amplifier and/or a single-ended sense amplifier (e.g., a sense amplifier coupled to a single digit line).

Column decoder transistors 232-n and 233-n are coupled to the sense amplifier 208-n, column decoder transistors 232-(n+1) and 233-(n+1) are coupled to the sense amplifier 208-n+1, and column decoder transistors 232-n+2 and 233-n+2 are coupled to the sense amplifier 208-n+2. The columns of memory cells include corresponding respective column decode transistor pairs (e.g., 232-n and 233-n, 232-(n+1) and 233-(n+1), 232-(n+2) and 233-(n+2) (referred to collectively as the column decode transistors of 232 and 233)) that can be operated via respective column decode signals (e.g., ColDec_n, ColDec_(n+1), and ColDec_(n+2), respectively). For example, one or more of the column decode transistors 232 and 233 can be enabled to transfer, via local I/O lines LIO 238-1 and LIOF 238-2, a data value from a corresponding sense amplifier 208 to a component external to the memory array 206, such as the host 102 described in association with FIG. 1.

In some embodiments, the memory array 206 can include one or more subarrays. As used herein, “subarray” refers to a subset of a memory array (e.g., the memory array 206). In some embodiments, rows and columns of a memory array coupled to a local I/O line can correspond to a subarray. For example, the word lines 236-m, 236-(m+1), 236-(m+2), 236-(m+3), and 236-(m+4) and the digit lines 230-n, 230-(n+1), and 230-(n+2), and the memory cells coupled thereto, can correspond to a subarray. The word lines 236-k, 236-(k+1), 236-(k+2), 236-(k+3), and 236-(k+4) and the digit lines 231-n, 231-(n+1), and 231-(n+2), and the memory cells coupled thereto, can correspond to another subarray. In some embodiments, the memory array 206 can be a bank. As used herein, “bank” refers a memory array of a memory device, such as the memory device 104 described in association with FIG. 1.

Although not illustrated by FIG. 2, the local I/O lines LIO 238-1 and LIOF 238-2 can be coupled to one or more I/O lines (e.g., global I/O lines) that provide communication between the memory array 206 and one or more components external to the memory array 206. In some embodiments, a multiplexer can couple multiple local I/O lines of the memory array 206 to a global I/O line. In some embodiments, a multiplexer can be coupled to multiple global I/O lines. For example, eight global I/O lines can be coupled to a multiplexer where each global I/O line coupled thereto provides a respective bit of a byte of data to be transferred to or from the memory array 206.

The sense amplifiers 208 can be electrically connected to the LIO 238-1 via the column decoder transistors 232-n, 232-(n+1), and 232-(n+2). The sense amplifiers 208 can be connected to the LIOF 238-2 via the column decoder transistors 233-n, 233-(n+1), and 233-(n+2). In some embodiments, the column decode transistors 232 and 233 can be coupled to respective sense amplifiers 208 and respective complementary digit line pairs 230-n/231-n, 230-(n+1)/231-(n+1), and 230-(n+2)/231-(n+2) such that disabling one or more of the column decode transistors 232 and 233 electrically connects and disconnects the sense amplifiers 208 from the LIO 238-1 and/or the LIOF 238-2. One or more of the column decode transistors 232 and 233 can be enabled to transfer a signal corresponding to a state (e.g., a logical data value such as logic “0” or logic “1”) of a memory cell and/or a logical data value stored by the sense amplifiers 208 to the LIO 238-1 and/or the LIOF 238-2.

The column decoder transistors 232 and 233 can be coupled to a column decoder (e.g., the column decoder 120 described in association with FIG. 1). The sense amplifiers 208 can be electrically connected to the LIO 238-1 and/or the LIOF 238-2 via the column decoder transistors 232 and 233 in association with operating the sense amplifiers 208 in a sense amplifier mode.

The sense amplifiers 208 can include equilibration circuitry 246 and a latch 247 (e.g., a static latch such as a cross coupled latch). The latch 247 can include a pair of cross coupled n-channel transistors (e.g., NMOS transistors) 243-1 and 243-2 having their respective sources selectively coupled to a reference voltage (e.g., ground). A respective source/drain region of the cross coupled n-channel transistors 243-1 and 243-2 can be coupled to a negative control signal line providing a negative control signal (e.g., RnlF). The cross coupled n-channel transistor 243-1 can have a source/drain region directly coupled to a latch node of the sense amplifiers 208 coupled to the digit lines 230. The cross coupled n-channel transistor 243-2 can have a source/drain directly coupled to a different latch node of the sense amplifiers 208 coupled to the digit lines 231.

The latch 247 can also include a pair of cross coupled p-channel transistors (e.g., PMOS transistors) 242-1 and 242-2. A respective source/drain region of the cross coupled p-channel transistors 242-1 and 242-2 can be coupled to a positive control signal line providing a positive control signal (e.g., ACT). The cross coupled p-channel transistor 242-1 can have a source/drain region directly coupled to a latch node of the sense amplifiers 208 coupled to the digit lines 230. The cross coupled p-channel transistor 242-2 can have a source/drain region directly coupled to a different latch node of the sense amplifiers 208 coupled to the digit lines 231.

A gate of the cross coupled n-channel transistor 243-1 and a gate of the cross coupled p-channel transistor 242-1 can be coupled to the latch node of the sense amplifiers 208 coupled to the digit lines 230. A gate of the cross coupled n-channel transistor 243-2 and a gate of the cross coupled p-channel transistor 242-2 are coupled to the latch node of the sense amplifiers 208 coupled to the digit lines 231.

The equilibration circuitry 246 can be configured to equilibrate the complementary digit line pairs 230-n/231-n, 230-(n+1)/231-(n+1), and 230-(n+2)/231-(n+2). The equilibration circuitry 246 can include a transistor 241 coupled between the complementary digit line pairs 230-n/231-n, 230-(n+1)/231-(n+1), and 230-(n+2)/231-(n+2). The equilibration circuitry 246 can also include transistors 240-1 and 240-2, each having a first source/drain region coupled together. A second source/drain region of the transistor 240-1 can be coupled to the corresponding digit line 230 and a second source/drain region of the transistor 225-2 can be coupled to the corresponding digit line 231. Gates of the transistors 241, 240-1, and 240-2 can be coupled together, and coupled to an equilibration control signal line providing an equilibration control signal (EQ). As such, activating EQ turns on the transistors 241, 240-1, and 240-2, which effectively shorts the complementary digit line pairs 230-n/231-n, 230-(n+1)/231-(n+1), and 230-(n+2)/231-(n+2) together and to an equilibration voltage (e.g., VDD/2).

In some embodiments, the transistors 241, 240-1, and 240-2 are n-channel transistors. However, embodiments of the present disclosure are not limited to the transistors of a particular conductivity type. For example, opposite control signals can be used with transistors of opposite conductivity type to implement same sense amplifier functionality.

When a memory cell is being sensed (e.g., read), the voltage on a digit line of one of the complementary digit line pairs 230-n/231-n, 230-(n+1)/231-(n+1), and 230-(n+2)/231-(n+2) can be slightly greater than the voltage on the other digit line of the pair. The ACT signal can then be driven high and the RnlF signal can be driven low to enable one or more of the sense amplifiers 208. The digit line of the pair having the lower voltage will turn on one of the PMOS transistor 242-1 or 242-2 to a greater extent than the other of the PMOS transistor 242-1 or 242-2. As a result, the digit line of the pair having the higher voltage is driven high to a greater extent than the other digit line.

Similarly, the digit line of one of the complementary digit line pairs 230-n/231-n, 230-(n+1)/231-(n+1), and 230-(n+2)/231-(n+2) having the higher voltage will turn on one of the NMOS transistor 243-1 or 243-2 to a greater extent than the other of the NMOS transistor 243-1 or 243-2. As a result, the digit line of the pair having the lower voltage is driven low to a greater extent than the other digit line. After a short delay, the digit line of the pair having the greater voltage can be driven to the voltage of the supply voltage (e.g., VDD) and the other digit line can be driven to the voltage of the reference voltage (e.g., ground). Therefore, the NMOS transistors 243-1 and 243-2 and the PMOS transistors 242-1 and 242-2 serve as a sense amplifier pair that amplify the voltage differential on the complementary digit line pairs 230-n/231-n, 230-(n+1)/231-(n+1), and 230-(n+2)/231-(n+2) and operate to latch a data value sensed from the memory cell.

The sense amplifiers 208 can be used in performance logical operations, such as logical AND/OR operations. In some embodiments, to perform a logical AND operation on data (e.g., operands) stored in at least two memory cells coupled to different rows (e.g., rows 234-k and 234-k+1) and to the same digit lines (e.g., non-reference digit line), the rows (e.g., the rows 234-k and 234-k+1) can be activated (turned on) along with another row of memory cells (e.g., the row 236-m+4) coupled to at least one memory cell (alternatively referred to as “reference memory cell”) of the another row storing logical “1”, which can be referred to as a “reference data value” (e.g., for logical AND operations). The memory cell storing a reference data value can be coupled to a different digit line (e.g., reference digit line) than the non-reference digit line coupled to the two rows coupled to the two memory cells. A sense amplifier 208 coupled to these reference and non-reference digit lines can be activated (fired) to sense (and store) a result of the logical AND operation. If both the memory cells of the row and the different row (e.g., the rows 234-k and 234-k+1) and the memory cells of the other row (e.g., the row 236-m+4) are storing a logical “1”, then activation of the three rows and the sense amplifiers results in the sense amplifiers sensing a logical “1”, which is the result of logical “1” AND logical “1”. If either of, or both of, the memory cells of the row and the different row (e.g., the rows 234-k and 234-k+1) is storing a logical “0”, then activation of the three rows and the sense amplifiers results in the sense amplifiers sensing a logical “0”, which is the result of logical “0” AND logical “1”, logical “1” AND logical “0”, and logical “0” AND logical “0”.

In some embodiments, to perform a logical OR operation on data (e.g., operands) stored in at least two memory cells coupled to different rows (e.g., rows 234-k and 234-k+1) and to the same digit lines, the rows (e.g., the rows 234-k and 234-k+1) can be activated (turned on) along with another row of memory cells (e.g., the row 236-m+4) coupled to at least one memory cell (alternatively referred to as “reference memory cell”) of the row storing logical “0”, which can be referred to as a “reference data value” (e.g., for logical OR operations). The memory cell storing a reference data value can be coupled to a different digit line (e.g., reference digit line) than the non-reference digit line coupled to the two rows coupled to the two memory cells. A sense amplifier 208 coupled to these reference and non-reference digit lines can be activated (fired) to sense (and store) a result of the logical OR operation. If either of, or both of, the memory cells of the row and the different row (e.g., the rows 234-k and 234-k+1) is storing a logical “0”, then activation of the three rows and the sense amplifiers results in the sense amplifiers sensing a logical “1”, which is the result of logical “0” OR logical “1”, logical “1” OR logical “0”, and logical “1” OR logical “1”. If both the memory cells of the row and the different row (e.g., the rows 234-k and 234-k+1) are storing a logical “0”, then activation of the three rows and the sense amplifiers results in the sense amplifier sensing a logical “0”, which is the result of logical “0” OR logical “0”.

In some embodiments, multiple logical operations (e.g., logical AND or OR operations) can performed concurrently (e.g., substantially concurrently) using multiple sense amplifiers 208. For example, the logical operations can be performed using data stored in all memory cells coupled to two rows (e.g., the rows 234-k, 234-k+1) on one side (non-reference side) as well as using (e.g., responsive to) reference data values stored in all memory cells coupled to one row (e.g., the row 236-m+4) on another side (reference side). As used herein, the “reference side” refers to one of complementary sides that includes reference digit lines and/or reference word lines, while the “non-reference side” refers to another one of the complementary sides includes non-reference digit lines and/or non-reference word lines. As used herein, the term “substantially” means that the characteristic need not be absolute, but is close enough so as to achieve the advantages of the characteristic. For example, “substantially concurrently” is not limited to operations that are performed absolutely concurrently and can include timings that are intended to be contemporaneous but may not be precisely concurrently.

Although embodiments are not so limited, reference data values for logical AND and OR operations can be stored in memory cells in a unit of row of memory cells. For example, while memory cells coupled to the row 236-m can all be configured to store a reference data value (e.g., “1”) for a logical AND operation, memory cells coupled to the row 236-m+1 can all be configured to store a reference data value (e.g., “0”) for a logical OR operation. Accordingly, in this configuration, logical operations performed substantially concurrently using (responsive to) reference data values stored on memory cells coupled to the same row can be the same logical (e.g., AND or OR) operation.

Although embodiments are not so limited, rows of memory cells on one side (e.g., either rows 236-k, . . . , 236-k+4 or 236-m, . . . , 236-m+4) can be configured for reference data values. For example, while data stored on memory cells coupled to rows 236-k (e.g., rows 236-k, . . . , 236-k+4) are used as operands for logical operations, memory cells coupled to rows 236-m (e.g., rows 236-m, . . . , 236-m+4) can be configured to store respective reference data values. However, embodiments are not so limited. For example, memory cells on the row coupled to reference digit lines can store different data values such that different logical (e.g., AND or OR) operations can be performed using (responsive to) the reference data values stored on (e.g., memory cells coupled to) the single row.

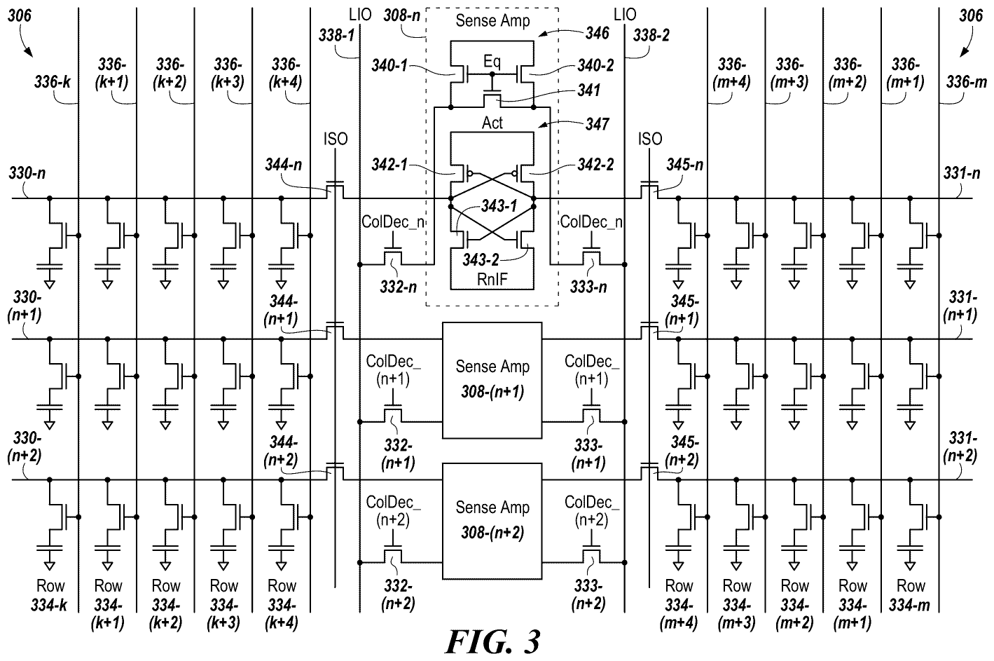

FIG. 3 is a schematic diagram illustrating rows 334 of a memory array 306 and sense amplifiers 308 that can perform logical operations using multiple digits lines 330, 331 in accordance with a number of embodiments of the present disclosure. The memory array 306 and the sense amplifiers 308 can be analogous to the memory array 206 and the sense amplifiers 208 described in association with FIG. 2.

FIG. 3 illustrates an embodiment of the present disclosure that differs from the embodiment illustrated by FIG. 2 in that additional transistors 344-n, 344-(n+1), and 344-(n+2) (referred collectively as the transistors 344) and transistors 345-n, 345-(n+1), and 345-(n+2) (referred collectively as the transistors 345) are included that are dedicated to isolating the sense amplifiers 308 from capacitance of the digit lines 330 and 331. The sense amplifiers 308 can be isolated (electrically disconnected) from capacitance of the digit lines 330 and 331 via the transistors 344 and 345, respectively, in association with operating the sense amplifiers 308 as a SRAM cache.

Each of the transistors 344 has a source/drain region coupled to a respective one of the digit lines 330 and another source/drain region coupled to one of the sense amplifiers 308 coupled to that digit line. Each of the transistors 345 has a source/drain region coupled to a respective one of the digit lines 331 and another source/drain region coupled to one of the sense amplifiers 308 coupled to that digit line. Gates of the transistors 344 and 345 can be coupled to a signal line by which a control signal ISO can be provided.

FIG. 3 illustrates the transistors 344 and 345 being n-channel transistors (e.g., NMOS transistor). Driving the control signal ISO high, for example, can enable the transistors 344 and 345 such that the sense amplifiers 308 are electrically connected to the memory array 306. Driving the control signal ISO low can disable the transistors 344 and 345 such that the sense amplifiers 308 are isolated (electrically disconnected) from capacitance of the digit lines 330 and 331, respectively. However, embodiments of the present disclosure are not limited to any of the transistors 344 and/or 345 being n-channel transistors. For example, the transistors 344 and 345 can be p-channel transistors (e.g., PMOS transistor). In such embodiments, driving the control signal ISO high can disable the transistors 344 and 345 such that the sense amplifiers 308 are isolated (electrically disconnected) from capacitance of the digit lines 330 and 331.

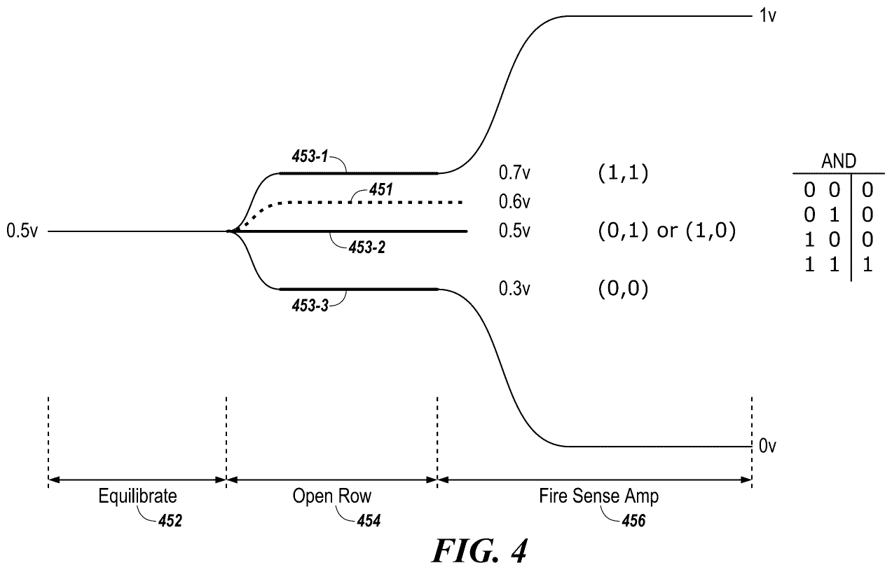

FIG. 4 illustrates various voltage levels of voltages at which digit lines are biased while a logical operation is being performed in accordance with a number of embodiments of the present disclosure. Although embodiments are not so limited, FIG. 4 illustrates the voltage levels in association with performing a logical “AND” operation.

A logical AND operation illustrated in FIG. 4 can be performed using at least three memory cells, three word lines (e.g., word lines 236, 336 illustrated in FIGS. 2-3) coupled to the three memory cells, and two digit lines (e.g., digit lines 230, 231, 330, 331 illustrated in FIGS. 2-3). For example, two memory cells that are coupled to the same digit line (e.g., a digit line 230, 330) can respectively store operands of a logical AND operation, while one memory cell that is coupled to a different digit line (e.g., a digit line 231, 331) can store a reference voltage corresponding to a reference data value whose binary value (alternatively referred to as a logical value) is specifically dedicated for performance of a logical AND operation. For example, a reference data value for a logical AND operation can be binary value “1”, although embodiments are not so limited. As described herein, the digit line that is coupled to a memory cell storing a reference data value can be alternatively referred to as a “reference digit line”. Further, the two digit lines can be those digit lines coupled to the same sense amplifier (e.g., a sense amplifier 208, 308). As further described herein, the reference data value operates to adjust a voltage differential sensed at the sense amplifier as desired in performing logical AND (e.g., or OR) operations.

During a phase 452, the two digit lines are equilibrated at a particular voltage level, such as at 0.5 V as illustrated in FIG. 4. During a phase 454, the three word lines (alternatively referred to as “rows”) are respectively activated. Although embodiments are not so limited, three word lines can be activated substantially concurrently.

When corresponding word lines are activated, each binary value “1” on the memory cells can increase a voltage level at which the respective digit line (to which two “activated” word lines are coupled to) by 0.1V, while each binary value “1” on the memory cells can lower a voltage level at which the respective digit line by 0.1V. For example, as illustrated in FIG. 4, two memory cells storing (e.g., operands of) two “1”s (e.g., “(1,1)” as illustrated in FIG. 4) can cause a voltage level of the digit line (e.g., at which the digit line is biased) to increase by 0.2 V (e.g., from the equilibrated voltage 0.5V to 0.7V) as indicated by 453-1; two memory cells storing “1” and “0” (e.g., “(0,1) or (1,0)” as illustrated in FIG. 4) can cause a voltage level of the digit line (e.g., at which the digit line is biased) to stay at 0.5V (e.g., 0.5V+0.1V−0.1V) as indicated by 453-2; and two memory cells storing two “0”s (e.g., “(0,0)” as illustrated in FIG. 4) can cause a voltage level of the digit line (e.g., at which the digit line is biased) to decrease by 0.2V (e.g., from the equilibrated voltage 0.5V to 0.3V) as indicated by 453-3.

Given that the reference data value is equal to a binary value “1”, the reference digit line is biased at 0.6V during the phase 454 and as indicated by 451 of FIG. 4. As a result, a differential voltage sensed at a sense amplifier is “negative” (e.g., a voltage level of the reference digit line is greater than a voltage level of the other digit line) unless the operands stored at the two memory cells are both “1” s. Accordingly, the activation (e.g., firing) of the sense amplifier during a phase 456 results in a differential voltage driven high to 1V (which corresponds to a binary value “1”) when the two operands are (1,1), while the differential voltage is driven low to 0V (which corresponds to a binary value “0”) when the two operands are (0,1), (1,0), and/or (0,0). A data value sensed at the sense amplifier as a result of activating the two digit lines and three word lines corresponds to a result of a logical AND operation.

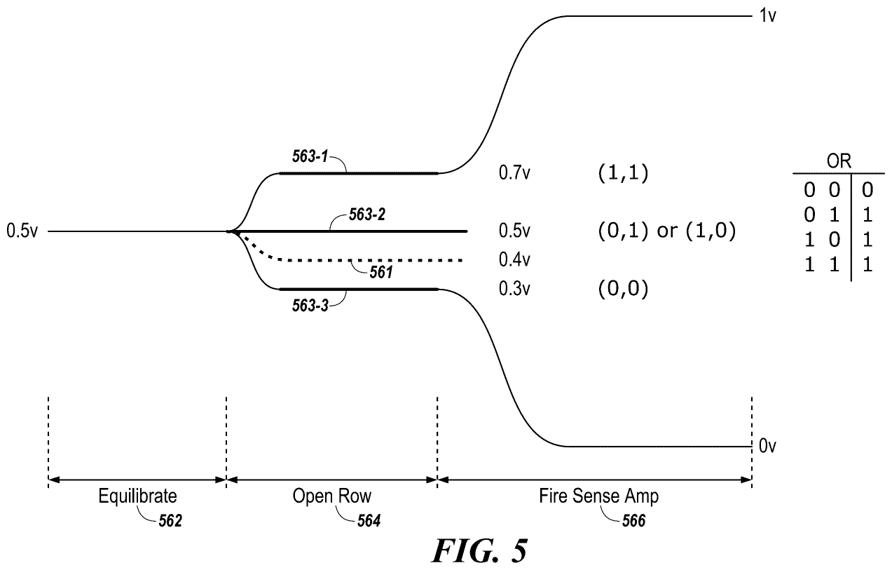

FIG. 5 illustrates various voltage levels of voltages at which digit/lines are biased while another logical operation is being performed in accordance with a number of embodiments of the present disclosure. Although embodiments are not so limited, FIG. 5 illustrates the voltage levels in association with performing a logical “OR” operation.

FIG. 5 is generally analogous to FIG. 4 except that a reference data value of “0” (as opposed to a reference data value of logical “1” used for logical AND operations) is used for performance of logical OR operations. For example, as opposed to the reference digit line being biased at 0.6V during the phase 454, the reference digit line corresponding to a reference data value of logical “0” is biased at 0.4V during the phase 564 and as indicated by 561 of FIG. 5. As a result, a differential voltage sensed at a sense amplifier is “positive” (e.g., a voltage level of the reference digit line is less than a voltage level of the other digit line) unless the operands stored at the two memory cells are both “0” s. Accordingly, the activation (e.g., firing) of the sense amplifier during a phase 566 results in a differential voltage driven low to 0V (which corresponds to a binary value “0”) when the two operands are (0,0), while the differential voltage is driven high to 1V (which corresponds to a binary value “1”) when the two operands are (0,1), (1,0), and/or (1,1). A data value sensed at the sense amplifier as a result of activating the two digit lines and three word lines corresponds to a result of a logical OR operation. As illustrated in association with FIGS. 4 and 5, logical (e.g., AND and/or OR) operations can be performed with one clock cycle, in which corresponding word lines, digit lines, and/or a sense amplifier are activated.

Performing logical operations, such as AND and/or OR logical operations, as described herein in connection with FIGS. 4-5 can provide benefits over those approaches that activates only one of two digit lines for performance of logical operations. For example, consider a configuration, in which reference data values are stored on the same side as those memory cells storing operands of logical operations such that performing the logical operations merely involves activating three word lines on a same side (e.g., activating a single digit line). The more word lines on the same side, the higher chance of noise and interference among the word lines, which potentially leads to errors during performance of the logical operations. On the other hand, diversifying a number of word lines (e.g., activated for performance of logical operations) over multiple digit lines can provide more precise voltage tuning capability on both sides, which can reduce the risk of noise and interference in activating the word lines.

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and processes are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
performing a logical operation on data values respectively stored in a first memory cell and a second memory cell coupled to a first digit line to which a sense amplifier is coupled by:
activating:
a first word line coupled to the first memory cell;
a second word line coupled to the second memory cell; and
a third word line coupled to a third memory cell, wherein the third memory cell is coupled to a second digit line to which the sense amplifier is coupled; and
activating the sense amplifier, wherein a data value sensed at the sense amplifier corresponds to a result of the logical operation.

2. The method of claim 1, wherein the third memory cell is configured to store a first reference data value or a second reference data value.

3. The method of claim 2, further comprising performing a logical AND operation on the data values respectively stored in the first memory cell and the second memory cell responsive to the third memory cell storing the first reference data value.

4. The method of claim 2, further comprising performing a logical OR operation on the data values respectively stored in the first memory cell and the second memory cell responsive to the third memory cell storing the second data value.

5. The method of claim 1, further comprising:
equilibrating the first, second, and third word lines prior to activating the first, second, and third word lines; and
activating the sense amplifier while the first, second, and third word lines are activated.

6. The method of claim 1, further comprising concurrently activating the first, second, and third word lines.

7. An apparatus, comprising:
a first digit line coupled to a first plurality of memory cells, the first plurality of memory cells being coupled to respective first word lines;
a second digit line coupled to a second plurality of memory cells, the second plurality of memory cells being coupled to respective second word lines;
a sense amplifier coupled to the first digit line and to the second digit line; and
a controller configured to perform a logical operation on data values stored in at least two of the first plurality of memory cells by:
activating corresponding first word lines to which the at least two memory cells are coupled;
activating a corresponding second word line to which a memory cell of the second plurality of memory cells is coupled, wherein the memory cell of the second plurality stores a voltage corresponding to a reference data value; and
activating the sense amplifier to store a result of the logical operation therein.

8. The apparatus of claim 7, wherein the controller is configured to concurrently activate the corresponding first word lines to which the at least two memory cells are coupled and the corresponding second word line to which the memory cell of the second plurality of memory cells is coupled.

9. The apparatus of claim 8, wherein the controller is configured to activate the sense amplifier while the corresponding first word lines to which the at least two memory cells are coupled and the corresponding second word line to which the memory cell of the second plurality of memory cells is coupled are concurrently activated.

10. The apparatus of claim 7, wherein the result of the logical operation is one of:
a first data value responsive to the reference data value being a first reference data value; or
a second data value responsive to the reference data value being a second reference data value.

11. The apparatus of claim 10, wherein:
the result of the logical operation is a logical AND result responsive to the reference data value being the first data value; and
the result of the logical operation is a logical OR result responsive to the reference data value being the second data value.

12. The apparatus of claim 11, wherein the corresponding second word line to which the memory cell of the second plurality of memory cells is coupled is also coupled to a plurality of additional memory cells, wherein the plurality of additional memory cells each store a reference voltage corresponding to the reference data value.

13. The apparatus of claim 7, wherein the apparatus comprises a dynamic random access memory (DRAM) device.

14. An apparatus, comprising:
a memory array comprising:
a plurality of memory cells coupled to a first digit line;
a first memory cell coupled to a second digit line and a first word line, the first memory cell configured to store a first reference data value having a first data value;
a second memory cell coupled to the second digit line and a second word line, the second memory cell configured store a second reference data value having a second data value; and
a sense amplifier coupled to the first and second digit lines; and
a controller is configured to, in order to perform a first logical operation on data values respectively stored in two memory cells of the plurality of memory cells coupled to the first digit line:
activate two word lines coupled to the two memory cells; and
activate, substantially concurrently with the two word lines being activated, the first word line to further adjust a voltage differential sensed at the sense amplifier based on the first reference data value stored on the first memory cell.

15. The apparatus of claim 14, wherein the controller is configured to, in order to perform a second logical operation on data values respectively stored in two memory cells of the plurality of memory cells coupled to the first digit line:
activate two word lines coupled to the two memory cells; and
activate, substantially concurrently with the two word lines being activated, the second word line to further adjust a voltage differential sensed at the sense amplifier based on the second reference data value stored on the second memory cell.

16. The apparatus of claim 14, wherein the activation of the first word line coupled to the first memory cell storing the first reference data value increases a voltage level at which the second digit line is biased.

17. The apparatus of claim 16, wherein the first logical operation is an AND logical operation.

18. The apparatus of claim 14, wherein the activation of the second word line coupled to the first memory cell storing the first reference data value decreases a voltage level at which the second digit line is biased.

19. The apparatus of claim 17, wherein the first logical operation is an OR logical operation.

20. The apparatus of claim 14, wherein the sense amplifier is one of plurality sense amplifiers, and wherein the controller is configured to perform a plurality of logical operation substantially concurrently using the plurality of sense amplifiers.
